(19) United States
(12) Patent Application Publication
(10) Pub. No.: US 2025/0338582 A1
(43) Pub. Date: Oct. 30, 2025

(54) SEMICONDUCTOR STRUCTURE AND METHOD FOR MANUFACTURING THE SAME

(71) Applicant: TAIWAN SEMICONDUCTOR MANUFACTURING COMPANY LTD., HSINCHU (TW)

(72) Inventors: TUNG-YANG LIN, NEW TAIPEI CITY (TW); RUEY-HSIN LIU, HSINCHU CITY (TW); LIANG-YU SU, YUNLIN COUNTY (TW)

(21) Appl. No.: 18/646,721

(22) Filed: Apr. 25, 2024

(51) Int. Cl. H01L 29/36; H01L 21/3115; H01L 21/762

(52) U.S. Cl. CPC H10D 62/60; H01L 21/31155; H01L 21/76224

(57) ABSTRACT

A semiconductor structure is provided. The semiconductor structure includes a substrate with a first dopant concentration, a barrier layer, an epitaxial layer with a second dopant concentration and a plurality of doped regions. The barrier layer is formed on the substrate and has a first conductivity type with a gradient doping profile. The barrier layer has a higher dopant concentration level at a middle portion of the barrier layer and has a lower dopant concentration level at a top of the barrier layer and at a bottom of the barrier layer. The epitaxial layer is formed on the barrier layer. The plurality of doped regions are formed on the epitaxial layer. The higher dopant concentration level is greater than the first dopant concentration and is also greater than the second dopant concentration.

### BACKGROUND

High-voltage devices or power devices are commonly used as switches or rectifiers in power electronic circuits or in integrated circuits. Some common power devices are the power diode, thyristor, power metal-oxide-semiconductor field-effect transistor (MOSFET), bipolar junction transistor (BJT) and insulated gate bipolar transistor (IGBT). A power diode or MOSFET operates on similar principles to its low-power counterpart, but is able to carry a larger amount of current and typically is able to support a larger reverse-bias voltage in the off-state.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a fragmentary cross-sectional view of a semiconductor structure in accordance with some embodiments of the present disclosure.

FIG. 2 is a doping profile of a barrier layer in the semiconductor structure in accordance with some embodiments of the present disclosure.

FIG. 3 is a fragmentary cross-sectional view of a semiconductor structure in accordance with some another embodiment of the present disclosure.

FIG. 4 is a fragmentary cross-sectional view of a semiconductor structure in accordance with some another embodiment of the present disclosure.

FIG. 5 is a fragmentary cross-sectional view of a semiconductor structure in accordance with some another embodiment of the present disclosure.

FIG. 6A is a fragmentary cross-sectional view of a semiconductor structure in accordance with some embodiments of the present disclosure illustrating the distribution of electron carriers in the semiconductor structure.

FIG. 6B is a fragmentary cross-sectional view of a semiconductor structure in accordance with some another embodiment of the present disclosure illustrating the distribution of electron carriers in the semiconductor structure.

FIG. 7 is a plot showing suppression ratio detected from a semiconductor structure in accordance with some embodiments of the present disclosure and that detected from a semiconductor structure without a barrier layer.

FIG. 8 is a flowchart illustrating a method of fabricating a semiconductor structure in accordance with some another embodiment of the present disclosure.

FIGS. 9 to 13 illustrate diagrammatic cross-sectional side views of some another embodiment of a semiconductor structure at various stages of fabrication, according to the method of FIG. 8.

FIG. 14 is a flowchart illustrating a method of fabricating a semiconductor structure in accordance with some another embodiment of the present disclosure.

FIGS. 15 to 20 illustrate diagrammatic cross-sectional side views of some another embodiment of a semiconductor structure at various stages of fabrication, according to the method of FIG. 14.

### DETAILED DESCRIPTION OF THE DISCLOSURE

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Also, the components disclosed herein may be arranged, combined, or configured in ways different from the exemplary embodiments shown herein without departing from the scope of the present disclosure. It is understood that those skilled in the art will be able to devise various equivalents that, although not explicitly described herein, embody the principles of the present invention.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

High-voltage devices are increasingly made smaller and smaller, reducing dimensions of various features. As the dimensions decrease, the high-voltage devices become increasingly susceptible to interference between adjacent power devices by unwanted cross talk between adjacent devices. In many instances, the cross talk is caused by lateral parasitic substrate current. For example, a lightly doped p-type substrate (e.g., P− substrate) may be overlaid with a P− epitaxial layer. Since the substrate and the epitaxial layer are both lightly doped and thus electron carriers received by the P− epitaxial layer may spread in the P− epitaxial layer or even spread to the P− substrate. Such structure would cause parasitic effects (such as undesired latch-up). A latch-up circuit is a type of short circuit with a low-impedance path between parasitic structures. The parasitic structure is usually equivalent to a thyristor, a positive-negative-positive-negative (PNPN) structure which acts as a positive-negative-positive (PNP) and a negative-positive-negative (NPN) transistor stacked next to each other. During a latch-up when one of the transistors is conducting, the other one begins conducting too. The transistors both keep each other in saturation for as long as the structure is forward-biased and some current flows through the transistors. A latch-up circuit can cause a product to fail.

To reduce the latch-up effect, a longer distance between different regions is required, which would enlarge chip size undesirably. The present disclosure provides a semiconductor structure with modified substrate without increasing chip size to mitigate the latch-up issue.

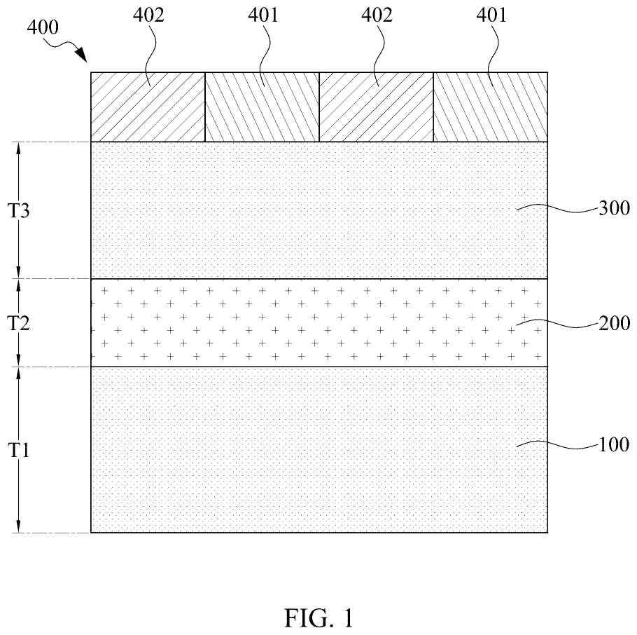

FIG. 1 illustrates a cross-sectional view of a semiconductor structure according to some embodiments of the present disclosure. The semiconductor structure includes a substrate 100, a barrier layer 200, an epitaxial layer 300 and a plurality of doped regions 400.

The substrate 100 can be a bulk semiconductor wafer having a first conductivity type at a first dopant concentration. For example, the substrate 100 can be a silicon wafer that can be doped with a p-type dopant. In some embodiments, the substrate 100 can be lightly doped with a p-type dopant, so the substrate 100 can be a P− substrate 100. In some embodiments, the substrate 100 is a silicon substrate doped with a p-type dopant such as B, Ga, or In, and thus serves as a p-type substrate. Alternatively, the substrate 100 includes another suitable semiconductor material. The substrate100 may optionally include a compound semiconductor and/or an alloy semiconductor. The substrate 100 has a first thickness T1.

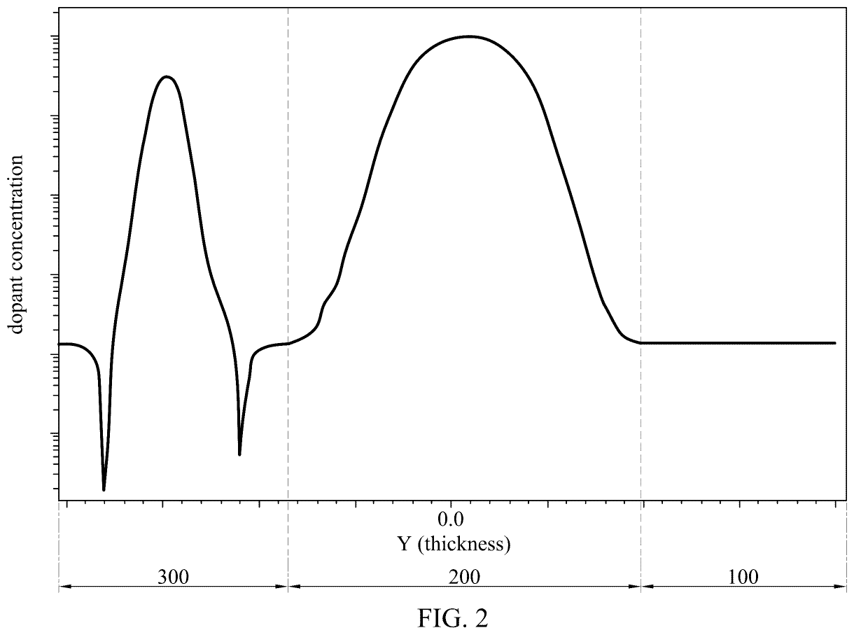

The barrier layer 200 is disposed on the substrate 100 and has the first conductivity type. For example, the barrier layer 200 can be doped with a p-type dopant and may be highly doped with a p-type dopant (e.g., P+ barrier layer) or even heavily doped with a p-type dopant (e.g., P++ barrier layer). The barrier layer 200 has a gradient doping profile as shown in FIG. 2. In view of FIG. 2, the barrier layer 200 has a gradient dopant concentration level. For example, the dopant concentration level may be the highest near a middle portion of the barrier layer 200 and drops toward top and bottom of the barrier layer 200. As an alternative example, the dopant concentration level may be the highest near the top of the barrier layer 200 and drops toward the bottom of the barrier layer 200. As another alternative example, the dopant concentration level may be the highest near a bottom of the barrier layer 200 and drops toward the top of the barrier layer 200. The barrier layer 200 has a second dopant concentration, which is an average dopant concentration of the barrier layer 200. The barrier layer 200 has a high-density region with a higher second dopant concentration and at least one low-density region with a lower second dopant concentration. In some embodiments, the high-density region may be in the middle of the barrier layer 200, which is sandwiched by two low-density regions. The lower second dopant concentration is equal to or higher than the first dopant concentration of the substrate 100. The higher second dopant concentration is higher than the first dopant concentration of the substrate 100.

In some embodiments, dopant concentration of each layer (including the substrate 100, the barrier layer 200 and the epitaxial layer 300) is indicated by its logarithm value. For instance, the first dopant concentration of the substrate 100, which may be a P− substrate, is equal to or less than about 10¹⁶ atoms/cm⁻³. In some embodiments, the first dopant concentration of the substrate 100 may range from about 10¹⁴ atoms/cm⁻³ to 10¹⁶ atoms/cm⁻³. In some embodiments, the first dopant concentration of the substrate 100 may about 10¹⁵ atoms/cm⁻³. The second dopant concentration of the barrier layer 200 may be equal to or greater than from about 10¹⁵ atoms/cm⁻³ and may range from about 10¹⁵ to 10²⁰ atoms/cm⁻³. The higher second dopant concentration of the barrier layer 200 may range from about 10¹⁶ atoms/cm⁻³ to about 10²⁰ atoms/cm⁻³; and in some embodiment, the higher second dopant concentration may range from about 1017 atoms/cm⁻³ to about 1019 atoms/cm⁻³. The lower second dopant concentration of the barrier layer 200 may be equal to or greater than 10¹⁵ atoms/cm⁻³. In some embodiments, the lower second dopant concentration of the barrier layer 200 may be equal to or greater than 10¹⁶ atoms/cm⁻³. The lower second dopant concentration of the barrier layer 200 may range from about 10¹⁵ atoms/cm⁻³ to about 10¹⁸ atoms/cm⁻³.

The barrier layer 200 has a second thickness T2. In some embodiments, the second thickness T2 may be identical to or different from the first thickness T1 of the substrate 100. In some embodiments, the second thickness T2 may be less than the first thickness T1 of the substrate 100. In some embodiments, the ratio of the second thickness T2 to the first thickness T1 can be from about 1:5 to about 2:1. In some embodiments, the ratio of the second thickness T2 to the first thickness T1 can be from about 1:4 to about 1:1. In some embodiments, the ratio of the second thickness T2 to the first thickness T1 can be from about 1:3 to about 1:2. When the second thickness T2 is thinner, the cost for manufacturing the semiconductor structure in accordance with the present disclosure can be reduced.

The epitaxial layer 300 is formed on the barrier layer 200 and has the first conductivity type at a third dopant concentration. The epitaxial layer 300 can be lightly doped with a p-type dopant, so the epitaxial layer 300 can be a P− epitaxial layer 300. The third dopant concentration may be substantially identical to the first dopant concentration and may be equal to or lower than the higher second dopant concentration. For instance, the third dopant concentration of the epitaxial layer 300, which may be a P− layer, is equal to or less than about 10¹⁶ atoms/cm⁻³. In some embodiments, the third dopant concentration of the epitaxial layer 300 may range from about 10¹⁴ atoms/cm⁻³ to 10¹⁶ atoms/cm⁻³. In some embodiments, the third dopant concentration of the epitaxial layer 300 may about 10¹⁵ atoms/cm⁻³. The epitaxial layer 300 has a third thickness T3. In some embodiments, the third thickness T3 of the epitaxial layer 300 may be identical to or different from the second thickness T2 of the barrier layer 200. In some embodiments, the third thickness T3 of the epitaxial layer 300 may be greater than the second thickness T2 of the barrier layer 200. In some embodiments, the ratio of the third thickness T3 to the second thickness T2 can be from about 5:1 to about 1:2. In some embodiments, the ratio of the third thickness T3 to the second thickness T2 can be from about 4:1 to about 1:1. In some embodiments, the ratio of the third thickness T3 to the second thickness T2 can be from about 3:1 to about 2:1.

The plurality of doped regions 400 overlay on the epitaxial layer 300 including at least one P-well regions 401 and at least one N-well regions 402. The P-well regions 401 may be formed within the epitaxial layer 300 using suitable doping method such as ion implantation and ion diffusion. In some embodiments, the P-well regions 401 are formed by any suitable deposition process, e.g., one or more of chemical vapor deposition (CVD), physical vapor deposition (PVD), molecular beam epitaxy (MBE), plasma-enhanced CVD (PECVD), sputtering, atomic layer deposition (ALD) and/or the like, over the epitaxial layer 300. Other fabrication techniques for forming the P-well regions 401 are also possible. The P-well regions 401 may include any suitable material such as one or more of silicon, germanium, silicon carbide, allium arsenide, gallium phosphide, indium phosphide, indium arsenide, antimonide, SiGe, GaAdP, AlInAs, AlGaAs, GaInAs, GaInP, and GaInAsP. The P-well regions 401 can be doped with any suitable P-type dopants. In some embodiments, the P-well regions 401 can be made of silicon and doped with one or more of boron, aluminum, nitrogen, gallium, and indium.

Interposed between adjacent P-well regions 401 are the N-well regions 402 which may be also formed using suitable doping method such as ion implantation and ion diffusion. The N-well regions 402 can be doped with N-type dopants. The N-well regions 402 can be made of one or more of silicon, germanium, silicon carbide, allium arsenide, gallium phosphide, indium phosphide, indium arsenide, antimonide, SiGe, GaAdP, AlInAs, AlGaAs, GaInAs, GaInP, and GaInAsP. In some embodiments, the N-well regions 402 are doped with any suitable N-type dopants such as one or more of phosphorous, arsenic, antimony, bismuth, lithium, etc. In some embodiments, the substrate 100, the barrier layer 200, the epitaxial layer 300, the P-well regions 401, and the N-well regions 402 are made of the same material, e.g., silicon.

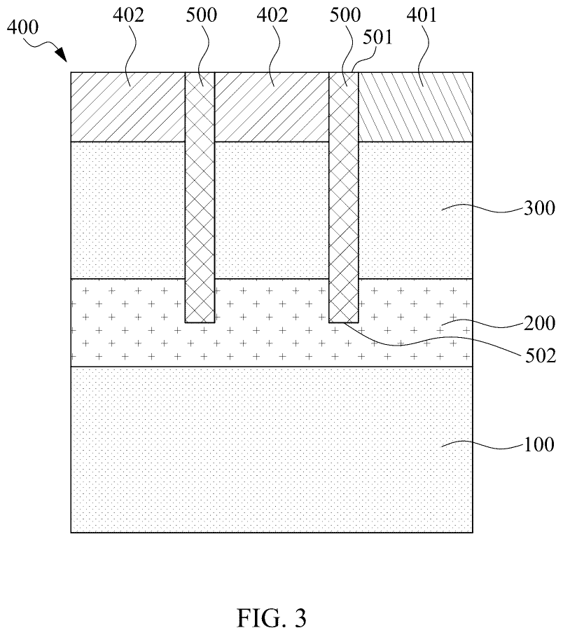

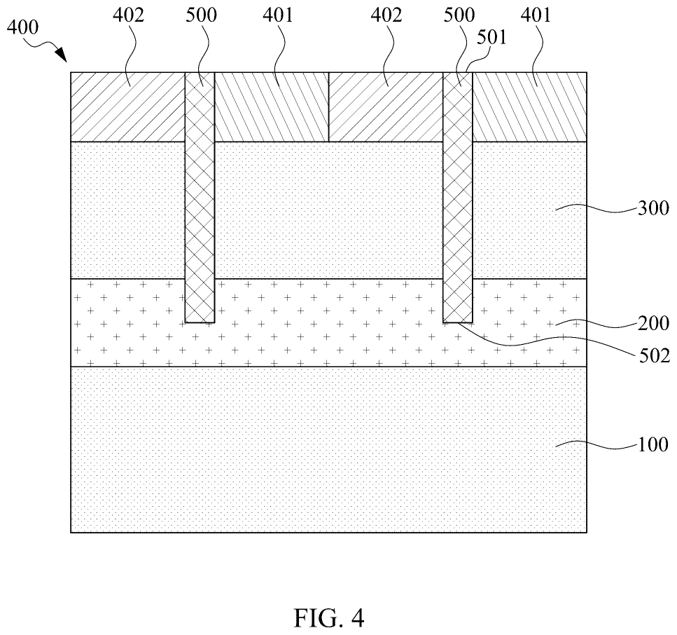

In some embodiments, as shown in FIGS. 3 and 4, the semiconductor structure further includes isolation structures 500. The isolation structures 500 is formed in the doped regions 400 to separate two well regions 401 and 402 and extends from the doped regions 400 to the barrier layer 200 through the epitaxial layer 300. In some embodiments, the isolation structures 500 may separate different types of doped regions 400 and also separate the same type of doped regions. For example, as shown in FIG. 3, one of the isolation structures 500 separates the P-well regions 401 and the N-well regions 402 and the other isolation structures 500 separates two N-well regions 402. In some alternative embodiments, the isolation structures 500 may separate different types of doped regions 400. As shown in FIG. 4, the isolation structures 500 separate the P-well regions 401 and the N-well regions 402. In some embodiments, the isolation structures 500 is formed between every two doped regions 400. In other embodiments, the isolation structures 500 is formed between some of the doped regions 400.

In some embodiments, the isolation structures 500 can be made of any suitable dielectric material, such as one or more of silicon oxide, spin-on-glass, silicon nitride, silicon oxynitride, fluorine-doped silicate glass (FSG), a low-k dielectric material. Isolation structures 500 can be shallow trench isolation (STI) structures. Each of the isolation structures 500 has a top 501 and a bottom 502. The top 501 of the isolation structures 500 may be coplanar with upper surfaces of the doped regions 400. The bottom 502 may be formed in the epitaxial layer 300. In some embodiments, the bottom 502 may be formed in a level between a top of the barrier layer 200 and a bottom of the barrier layer 200. In some embodiments, the bottom 502 may be formed near the top or the bottom of the barrier layer 200. In some embodiments, the bottom 502 of the isolations structure 500 may be formed in an area of the barrier layer 200 with the highest dopant concentration level. In some embodiments, when the dopant concentration level is the highest near a middle portion, which is a portion between the top and the bottom of the barrier layer 200, the bottom 502 of the isolation structure 500 may be formed in the middle portion of the barrier layer 200. In some embodiments, the bottom 502 of the isolation structure 500 may be formed near the upper surface of the barrier layer 200 when the dopant concentration level is the highest near the top of the barrier layer 200. In some embodiments, the bottom 502 of the isolation structure 500 may be formed near the bottom of the barrier layer 200 when the dopant concentration level is the highest near a bottom of the barrier layer 200.

In some embodiments, the isolation structure 500 protrudes into the barrier layer 200 at a depth, which is equal to between about 1/10 times and about 9/10 times of the second thickness T2 of the barrier layer 200. In some embodiments, the depth of the isolation structure 500 may be equal to between about ⅕ times and about ⅘ times of the second thickness T2 of the barrier layer 200. In some embodiments, the depth of the isolation structure 500 may be equal to between about ⅖ times and about ⅗ times of the second thickness T2 of the barrier layer 200. In some embodiments, the depth of the isolation structure 500 may be equal to between about ¾ times and about ¼ times of the second thickness T2 of the barrier layer 200. In some embodiments, the depth of the isolation structure 500 may be equal to about ½ times of the second thickness T2 of the barrier layer 200.

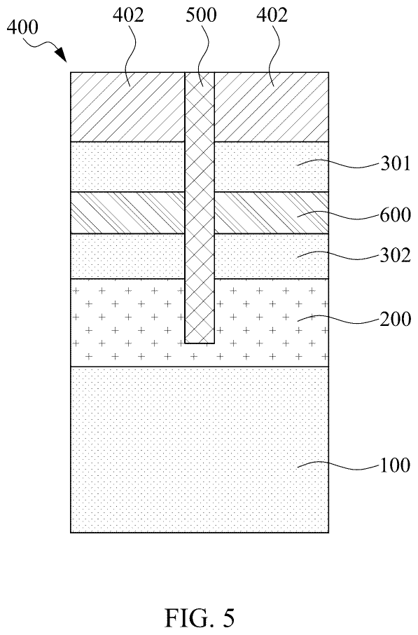

In some embodiments, as shown in FIG. 5, the semiconductor structure further comprises one or more inserting layers 600 disposed in the epitaxial layer 300 to separate the epitaxial layer 300 into an upper portion 301 and a lower portion 302 depending on various design requirements. In some embodiments, the inserting layer 600 includes one or more of silicon, germanium, silicon carbide, allium arsenide, gallium phosphide, indium phosphide, indium arsenide, antimonide, SiGe, GaAdP, AlInAs, AlGaAs, GaInAsP, GaInP, and GaInAsP, and can be doped with any suitable dopants. For example, the inserting layer 600 may be doped with N-type dopants to reduce noise between the doped regions 400 and the substrate 100. In some embodiments, the inserting layer 600 is made of silicon and can be doped with N-type dopants such as one or more of phosphorous, arsenic, antimony, bismuth, lithium, etc. In some embodiments, the inserting layer 600 can be formed by any suitable process such as ion implantation, ion diffusion, and/or in-situ doping with epitaxial deposition. Other fabrication techniques for forming the inserting layer 600 are also possible.

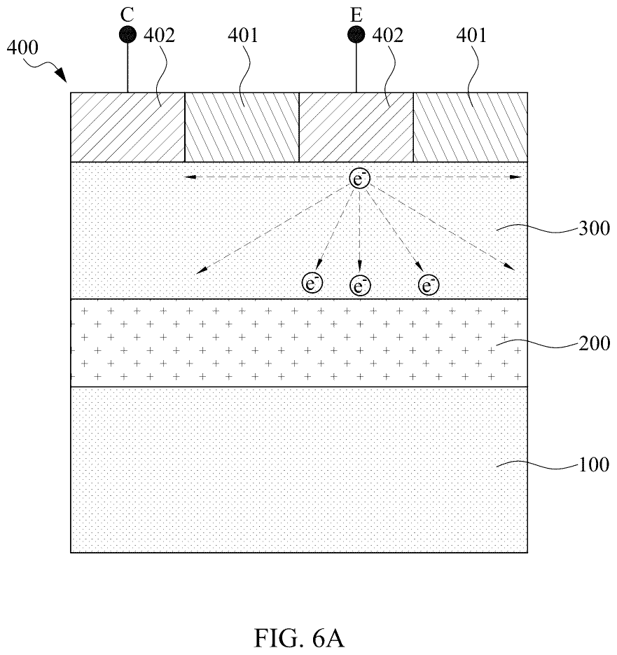

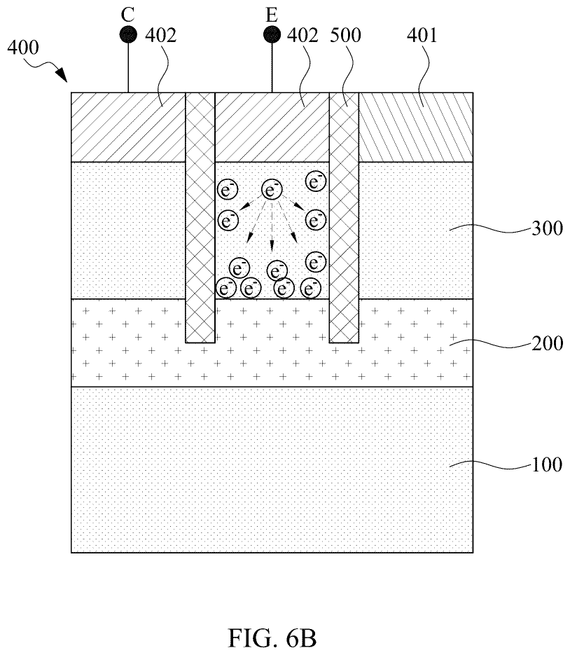

FIGS. 6A and 6B show the advantage of the semiconductor structure in accordance with some embodiments of the present disclosure. Electron carriers e⁻ may be emitted from an emitter E toward one of the doped regions 400 of the semiconductor structure (one of the N-well regions 402 as shown in FIGS. 6A and 6B) and a collector C may receive electron carriers e leaked from another one of the doped regions 400 (the other one of the N-well regions 402 as shown in FIGS. 6A and 6B). It was found that due to the barrier layer 200, the epitaxial layer 300 may suppress injection of the electron carriers e. Further, as shown in FIG. 6B, due to the isolation structures 500, the electron carriers e may be blocked by the barrier layer 200 and the isolation structures 500.

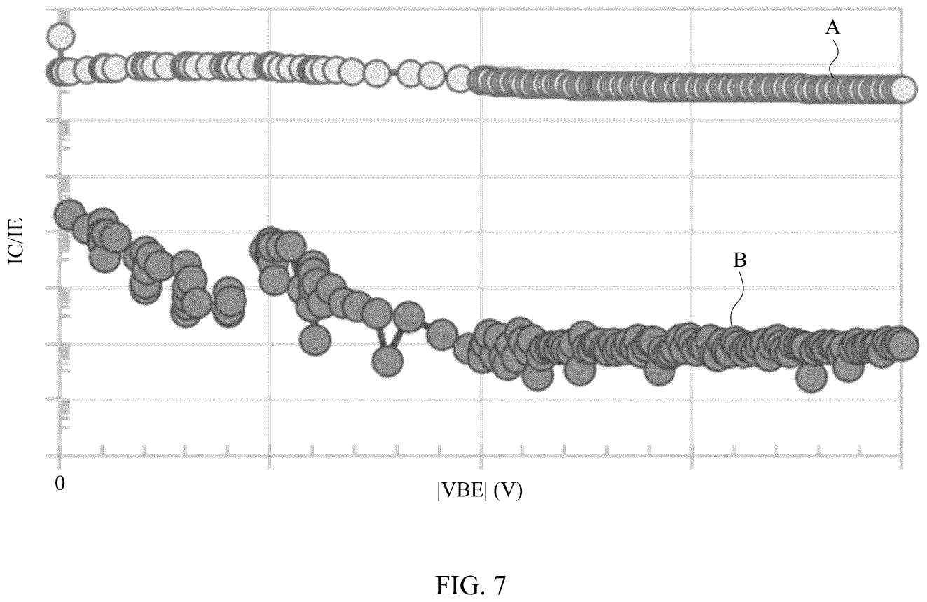

Further referring to FIG. 7, the X axis represents the emitter voltage VBE and the Y-axis on the left side of the figure represents a ratio of the collector current IC to the emitter current IE (“suppression ratio”). Curve A shows the suppression ratio IC/IE detected from a semiconductor structure without the barrier layer 200 and curve B shows the suppression ratio IC/IE detected from a semiconductor structure with the barrier layer 200 in accordance with some embodiments of the present disclosure. A higher suppression ratio IC/IE indicates that more electron carriers e are detected by the collector C, which may result in the latch-up effect. A lower suppression ratio IC/IE indicates that fewer electron carriers e⁻ are detected by the collector C, which is desired. According to FIG. 7, curve B show lower suppression ratio IC/IE, which demonstrates that the semiconductor structure with the barrier layer 200 in accordance with some embodiments of the present disclosure can reduce lateral injection and decrease the occurrence of the latch-up effect.

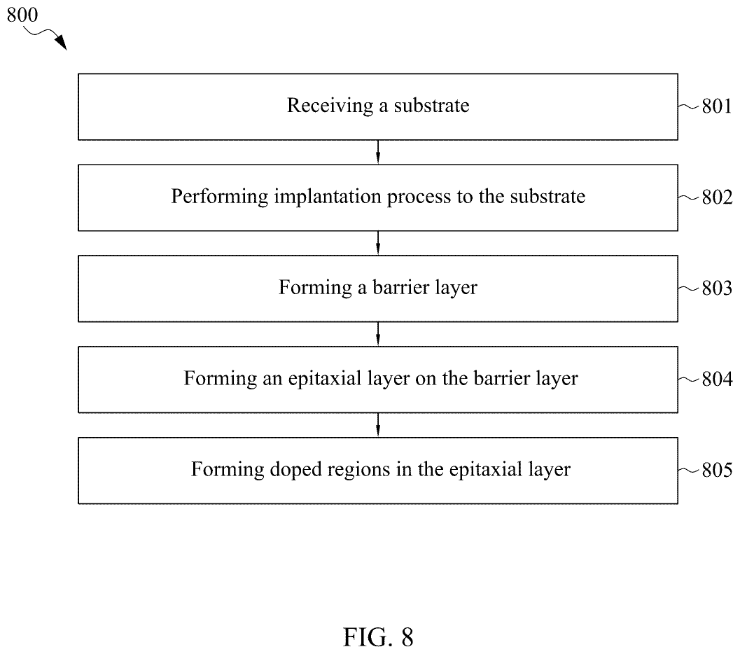

FIG. 8 is a flowchart representing a method 800 of manufacturing a semiconductor structure according to various aspects of the present disclosure in accordance with some embodiments. In some embodiments, the method 800 of manufacturing the semiconductor structure includes a number of operations (801, 802, 803, 804 and 805). The method 800 of manufacturing the semiconductor structure will be further described according to one or more embodiments. It should be noted that the operations of the method 800 may be rearranged or otherwise modified within the scope of the various aspects. It should further be noted that additional processes may be provided before, during, and after the method 800, and that some other processes may be only briefly described herein.

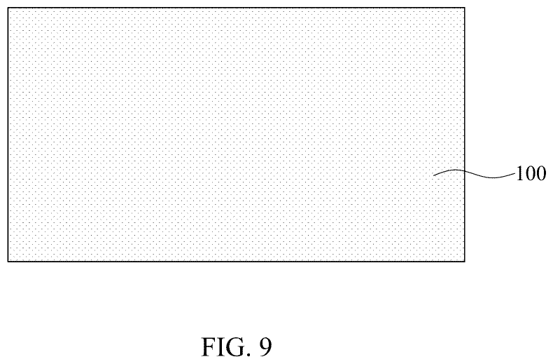

As shown in FIG. 9, method 800 begins at operation 801 by providing or receiving a substrate 100. The substrate 100 is usually a silicon substrate, but may be other semiconductor substrates such as silicon carbide (SiC), silicon dioxide, aluminum oxide, sapphire, germanium, gallium arsenide (GaAs), or indium phosphide (InP). These serve as the foundation upon which power devices such as transistors and diodes are deposited. In some embodiments, the substrate 100 is lightly doped with dopants of a first conductivity type (e.g., P-type) and thus to form a lightly doped p-type substrate (i.e., P− substrate).

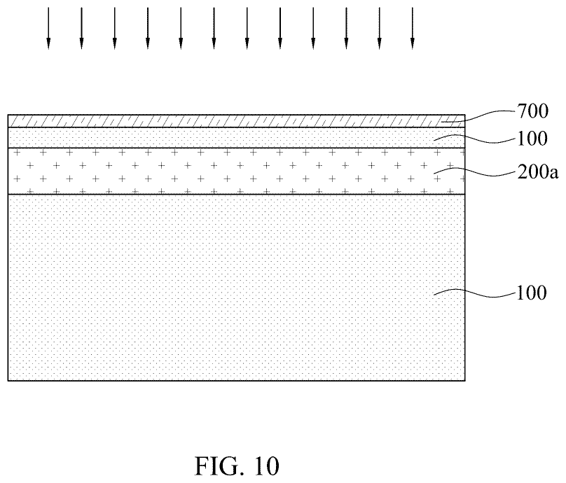

At operation 802, in view of FIG. 10, an implantation process is performed by doping the substrate 100 with dopants to form a barrier precursor layer 200a in the substrate 100 at a predetermined depth. In some embodiments, a buffer layer 700 can be formed on the substrate 100 to cover an upper surface of the substrate 100 before performing the implantation process and to protect the upper surface of the substrate 100 during the implantation process. The buffer layer 700 can be an oxide, such as SiO₂ and the like.

The implanted dopants comprise p-type dopants in some embodiments. The p-type dopants may comprise B, Ga, or In implanted to a concentration equal to or greater than from about 10¹⁵ atoms/cm⁻³, so that the barrier precursor layer 200a is highly doped with a p-type dopant (e.g., P+ layer) or even heavily doped with a p-type dopant (e.g., P++ layer). In some embodiments, the concentration may range from about 10¹⁵ atoms/cm⁻³ to 10²⁰ atoms/cm⁻³. The ion implantation energy, dosage, and temperature of the substrate 100 used during the implantation processes may be designed to control the penetration depth of the dopants in the substrate 100, so that a barrier precursor layer 200a can be formed at a predetermined depth in the substrate 100. As shown in FIG. 10, the barrier precursor layer 200a is formed in the substrate 100 and away from the upper surface of the substrate 100 in a distance, which is less than a thickness of the barrier precursor layer 200a.

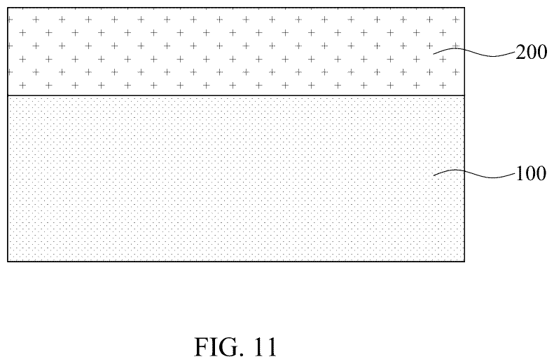

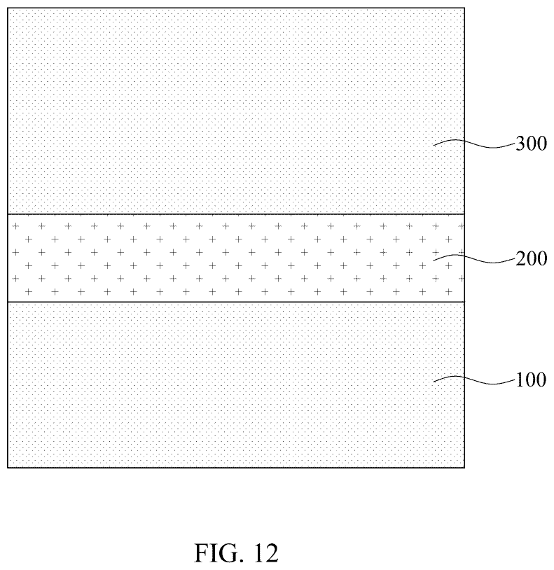

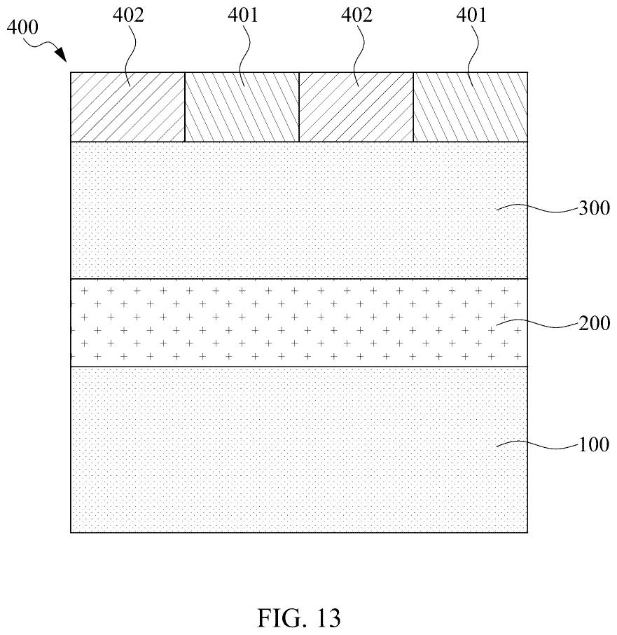

During operation 803, the buffer layer 700 can be removed and a heating process (such as annealing process) may be performed after the implantation process to drive the dopants to diffuse from the barrier precursor layer 200a into neighboring regions of the substrate 100 so as to form a barrier layer 200, as shown in FIG. 11, which has an increased thickness than the thickness of the barrier precursor layer 200a due to the diffusion of the dopants. Dopants can be diffused to the predetermined depth by controlling the concentration of dopants in the barrier precursor layer 200a, the heating temperature, the heating time and so on. Therefore, the thickness of the barrier layer 200 may depend on the diffusion of dopants. The boundary between the barrier layer 200 and the substrate define a bottom of the barrier layer 200 and also define a top of the substrate 100. In this way, a gradient doping profile is therefore formed; and in some embodiments, the highest concentration level may be near a middle portion of the barrier layer 200 and drops toward top and bottom of the barrier layer 200. The annealing process may be a rapid thermal annealing (RTA) process, a millisecond annealing (MSA) process, a laser annealing process and/or the like.

At operation 804, an epitaxial layer 300 can be formed by applying semiconductive material on the barrier layer 200and performing an epitaxial growth process in some embodiments, for example. The epitaxial layer 300 may be formed using metal-organic chemical vapor deposition (MOCVD), molecular beam epitaxy (MBE), liquid phase epitaxy (LPE), vapor phase epitaxy (VPE), selective epitaxial growth (SEG), the like, or a combination thereof. The semiconductive material comprises Si, SiGe, Ge, GeSn, SiGeSn, or an III-V material in some embodiments, for example.

The method 800 continues to operation 805, in which an upper portion of the epitaxial layer 300is doped with a desired doping level for forming doped regions 400. Depending on the type of the doped regions 400, the operation 805 typically involves multi-step implantation of different materials into the upper portion of the epitaxial layer 300 to form P-well regions 401 and N-well regions 402 in the upper portion of the epitaxial layer 300. Before forming the doped regions 400, the epitaxial layer 300 may be fabricated to form one or more regions (with different type of dopants or different concentrations of dopants from those of the epitaxial layer 300) in the epitaxial layer 300, such as an inserting layer 600 as shown in FIG. 5.

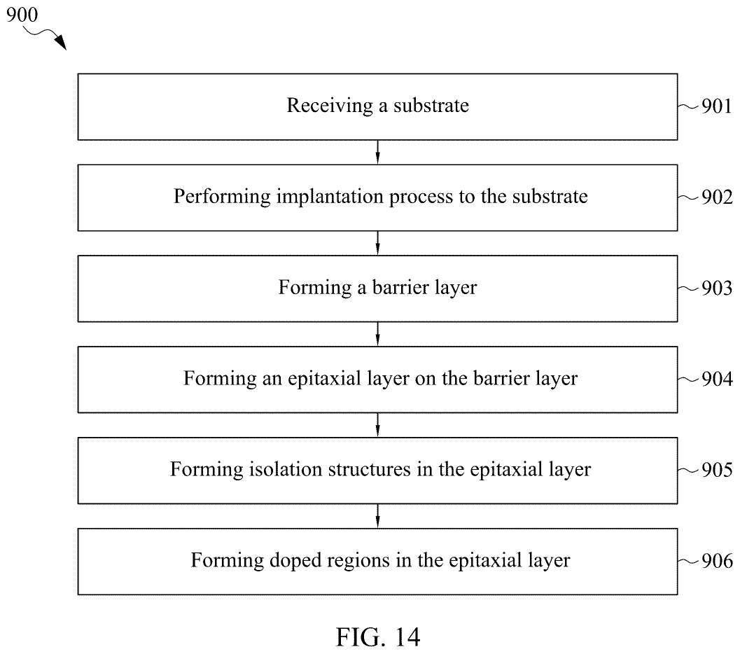

FIG. 14 is a flowchart representing a method 900 of manufacturing a semiconductor structure according to various aspects of the present disclosure in accordance with some another embodiment. Method 900 of manufacturing the semiconductor structure includes a number of operations (901, 902, 903, 904, 905 and 906). It should be noted that the operations of the method 900 may be rearranged or otherwise modified within the scope of the various aspects. It should further be noted that additional processes may be provided before, during, and after the method 900, and that some other processes may be only briefly described herein.

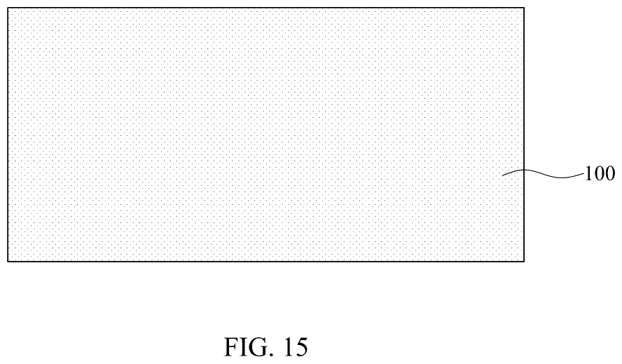

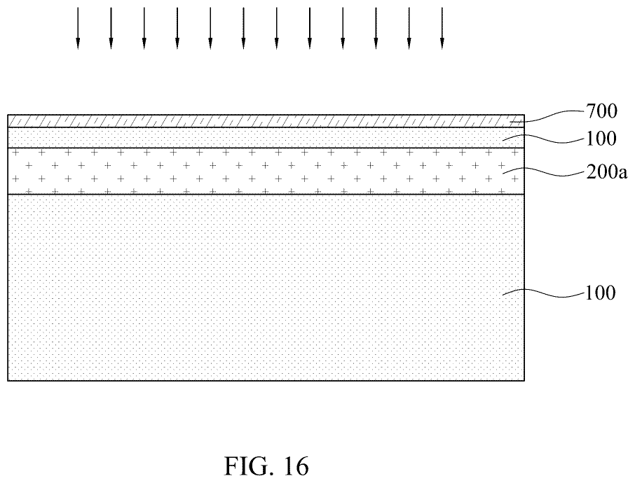

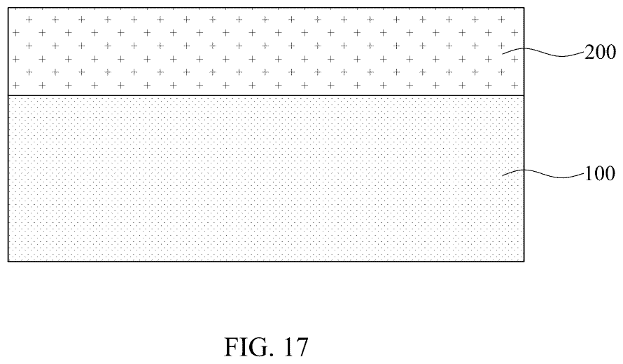

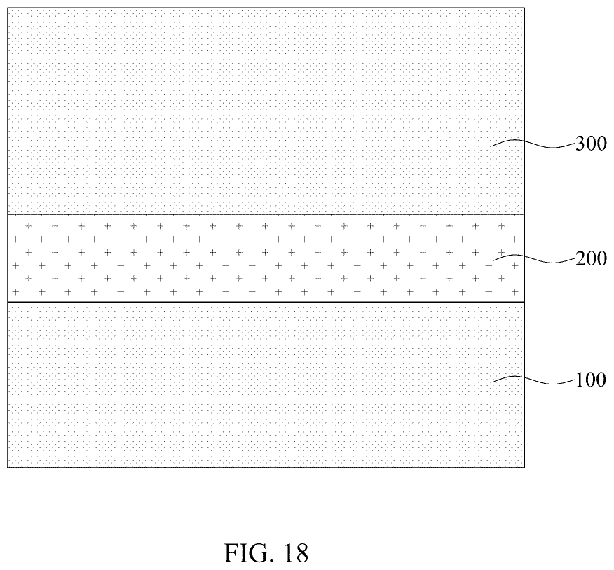

As shown in FIGS. 15 to 18, operations 901 to 904 of method 900 include receiving a substrate 100 at operation 901 in view of FIG. 15, performing implantation process to the substrate 100 at operation 902 in view of FIG. 16, forming a barrier layer 200 at operation 903 in view of FIG. 17 and forming an epitaxial layer 300 on the barrier layer 200 at operation 904 in view of FIG. 18, which are similar to operations 801 to 803 of method 900 and thus repeated descriptions of operations 901 to 904 are omitted for brevity.

At operation 905, isolation structures 500 can be formed by etching trenches (not shown) through the epitaxial layer 300 and extending to the barrier layer 200 via an etching process and filling dielectric materials to the trenches. The trenches may be shallow or deep and divide the epitaxial layer 300 into different doped regions 400 for power devices, which are formed next to the isolation structures 500. In some embodiments, one trench is used between power devices. In other embodiments, two or more trenches are used between power devices. Depending on the shape of trenches, various techniques may be used to etch the trenches. For shallow trenches, a photoresist pattern covers portions of the epitaxial layer 300, usually in a grid/mesh pattern. The epitaxial layer 300 is then subjected to dry etching or wet etching. Plasma assisted dry etch is used for deep trenches. Shallow trenches may be etched using dry etch or wet etch methods. Different etch methods and process parameters allow different trench shapes to form. Plasma etch techniques are used with biasing of the epitaxial layer 300 to direct the etchants at a normal angle into the epitaxial layer 300 such that a substantially vertical trench without much under etch is formed. Because of process limitations, a deep trench is usually formed with a small incline angle such that the bottom of the trench is smaller than the opening. For shallow trenches, the trench shape can be made substantially rectangular. The size and shape of trench depends on the amount of isolation desired between the doped regions 400. When two trenches are formed between the doped regions 400, a latch-up rule determines the minimum distance between nearest edges of the two trenches. In other words, a smaller latch-up rule allows the doped regions 400 to be placed closer together and more devices may be packed in a die.

In some embodiments, the trench is extended from an upper portion of the epitaxial layer 300 through the epitaxial layer 300 toward the barrier layer 200. In some embodiments, the bottom of the trench may be formed in the area of the barrier layer 200 with the highest dopant concentration level. In some embodiments, the bottom of the trench may be formed in the middle portion of the barrier layer 200 when the dopant concentration level is the highest near the middle portion of the barrier layer 200. In some embodiments, the bottom of the trench may be formed near the upper surface of the barrier layer 200 when the dopant concentration level is the highest near a top surface of the barrier layer 200. In some embodiments, the bottom of the trench may be formed near the bottom of the barrier layer 200 when the dopant concentration level is the highest near a bottom of the barrier layer 200.

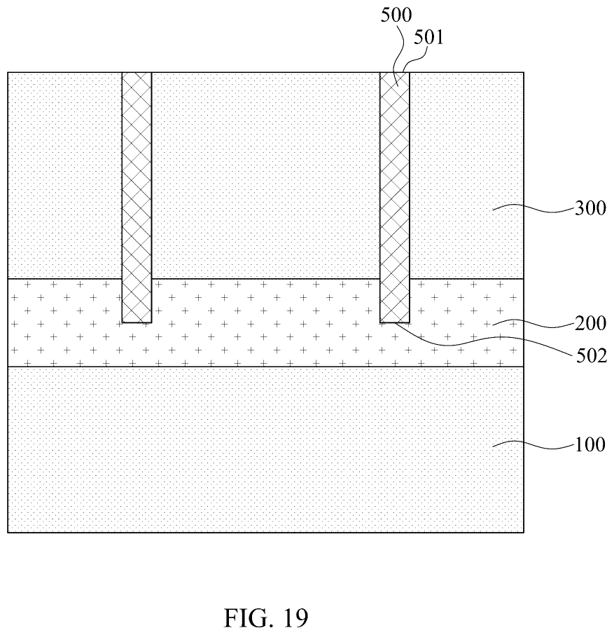

The trenches are filled with dielectric material to form the isolation structure 500 as shown in FIG. 19. The dielectric material is usually silicon oxide deposited using high density plasma chemical vapor deposition (HDPCVD). HDPCVD is used to deposit in the trenches having high aspect ratios by concurrent deposition and etching. As material is deposited into the bottom of the trench, plasma etching keeps overhangs at the opening of the trench from closing the opening.

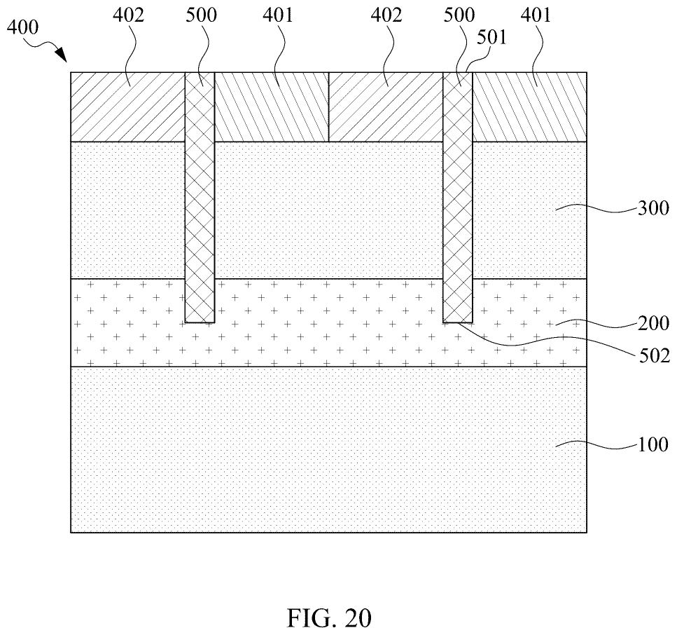

At operation 906, the doped regions 400 are formed in an upper portion of the epitaxial layer 300 adjacent to the isolation structure 500 as shown in FIG. 20. Depending on the type of the doped regions 400, multi-step implantation of different materials may be performed to form at least one P-well regions 401 and at least one N-well regions 402 in the upper portion of the epitaxial layer 300.

The barrier layer 200 with a higher dopant concentration than the substrate 100 and the epitaxial layer 300 provides recombination and suppresses minority carrier spread and thus forms a small minority carrier lifetime region. Such low resistivity barrier layer 200 achieves a low suppression ratio IC/IE and reduces injection of electron carriers with a cost-efficient way.

In some embodiments, a semiconductor structure comprises a barrier layer formed on a substrate and having a first conductivity type with a gradient doping profile, wherein the barrier layer has a higher dopant concentration level at a middle portion of the barrier layer and has a lower dopant concentration level at a top of the barrier layer and at a bottom of the barrier layer; an epitaxial layer formed on the barrier layer; and a plurality of doped regions formed on the epitaxial layer.

In some embodiments, a semiconductor structure comprises a substrate being doped with a p-type dopant at a first dopant concentration; a barrier layer formed on the substrate and being doped with the p-type dopant at a gradient doping profile including a higher second dopant concentration and a lower second dopant concentration; an epitaxial layer formed on the barrier layer and being doped with the p-type dopant at a third dopant concentration; a plurality of doped regions formed on the epitaxial layer; and at least one isolation structure formed in the doped regions to separate two of the doped regions and extending from the doped regions to the barrier layer through the epitaxial layer, wherein the higher second dopant concentration is greater than the first dopant concentration, greater than the lower second dopant concentration and greater than the third dopant concentration.

In some embodiments, a method of manufacturing a semiconductor structure comprises receiving a substrate; performing an implantation to the substrate with dopants to form a barrier precursor layer in the substrate; heating the substrate with the barrier precursor layer to form a barrier layer with a gradient doping profile; forming an epitaxial layer on the barrier layer; and forming doped regions in an upper portion of the epitaxial layer, wherein the barrier layer has a higher dopant concentration level at a middle portion of the barrier layer and has a lower dopant concentration level at a top of the barrier layer and at a bottom of the barrier layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising
a barrier layer formed on a substrate and having a first conductivity type with a gradient doping profile, wherein the barrier layer has a higher dopant concentration level at a middle portion of the barrier layer and has a lower dopant concentration level at a top of the barrier layer and at a bottom of the barrier layer;
an epitaxial layer formed on the barrier layer; and
a plurality of doped regions formed on the epitaxial layer.

2. The semiconductor structure of claim 1, wherein
the substrate has the first conductivity type with a first dopant concentration, which is lower than the higher dopant concentration level of the barrier layer; and
the epitaxial layer has the first conductivity type with a second dopant concentration, which is lower than the higher dopant concentration level of the barrier layer,
wherein the first conductivity type is p-type.

3. The semiconductor structure of claim 2, wherein
the first dopant concentration of the substrate is equal to or less than about 10¹⁶ atoms/cm⁻³,
the higher dopant concentration level of the barrier layer ranges from about 10¹⁶ atoms/cm⁻³ to about 10²⁰ atoms/cm⁻³; and
the second dopant concentration of the epitaxial layer is equal to or less than about 10¹⁶ atoms/cm⁻³.

4. The semiconductor structure of claim 2, wherein
the first dopant concentration of the substrate is equal to or less than about 10¹⁶ atoms/cm⁻³,
the lower dopant concentration level of the barrier layer is equal to or greater than about 10¹⁵ atoms/cm⁻³; and
the second dopant concentration of the epitaxial layer is equal to or less than about 10¹⁶ atoms/cm⁻³.

5. The semiconductor structure of claim 2, wherein the first dopant concentration of the substrate is substantially identical to the second dopant concentration of the epitaxial layer.

6. The semiconductor structure of claim 1, wherein
the substrate has a first thickness; and
the barrier layer has a second thickness,
wherein a ratio of the second thickness to the first thickness is from about 1:5 to about 2:1.

7. The semiconductor structure of claim 1, wherein
the substrate has a first thickness;
the barrier layer has a second thickness; and
the epitaxial layer has a third thickness,
wherein the second thickness of the barrier layer is less than the first thickness of the substrate; and
wherein a ratio of the third thickness to the second thickness is from about 5:1 to about 1:2.

8. The semiconductor structure of claim 1, wherein
the substrate has a first thickness;
the barrier layer has a second thickness; and
the epitaxial layer has a third thickness,
wherein the second thickness of the barrier layer is less than the first thickness of the substrate; and
wherein the third thickness of the epitaxial layer is greater than the second thickness of the barrier layer.

9. A semiconductor structure, comprising
a substrate being doped with a p-type dopant at a first dopant concentration;
a barrier layer formed on the substrate and being doped with the p-type dopant at a gradient doping profile including a higher second dopant concentration and a lower second dopant concentration;
an epitaxial layer formed on the barrier layer and being doped with the p-type dopant at a third dopant concentration;
a plurality of doped regions formed on the epitaxial layer; and
at least one isolation structure formed in the doped regions to separate two of the doped regions and extending from the doped regions to the barrier layer through the epitaxial layer,
wherein the higher second dopant concentration is greater than the first dopant concentration, greater than the lower second dopant concentration and greater than the third dopant concentration.

10. The semiconductor structure of claim 9, wherein
the substrate has a first thickness;
the barrier layer has second thickness; and
the epitaxial layer has a third thickness,
wherein a ratio of the second thickness to the first thickness is from about 1:5 to about 2:1; and
wherein a ratio of the third thickness to the second thickness is from about 5:1 to about 1:2.

11. The semiconductor structure of claim 10, wherein the isolation structure protrudes into the barrier layer at a depth, which is equal to between about 1/10 times and about 9/10 times of the second thickness of the barrier layer.

12. The semiconductor structure of claim 9, wherein
the barrier layer has a high-density region with the higher second dopant concentration and at least one low-density region with the lower second dopant concentration; and
the isolation structure has a top, which is coplanar with upper surfaces of the doped regions, and a bottom formed in the high-density region.

13. The semiconductor structure of claim 12, wherein the barrier layer has two low-density regions formed near a top and a bottom of the barrier layer, respectively, and wherein the high-density region of the barrier layer is in a middle of the barrier layer, which is sandwiched by the two low-density regions.

14. The semiconductor structure of claim 9, further comprising one or more inserting layers disposed in the epitaxial layer to separate the epitaxial layer into an upper portion and a lower portion.

15. A method of manufacturing a semiconductor structure, comprising
receiving a substrate;
performing an implantation to the substrate with dopants to form a barrier precursor layer in the substrate;
heating the substrate with the barrier precursor layer to form a barrier layer with a gradient doping profile;
forming an epitaxial layer on the barrier layer; and
forming doped regions in an upper portion of the epitaxial layer,
wherein the barrier layer has a higher dopant concentration level at a middle portion of the barrier layer and has a lower dopant concentration level at a top of the barrier layer and at a bottom of the barrier layer.

16. The method of claim 15, wherein
the substrate has a first conductivity type with a first dopant concentration, which is lower than the higher dopant concentration level of the barrier layer; and
the epitaxial layer has the first conductivity type with a second dopant concentration, which is lower than the higher dopant concentration level of the barrier layer,
wherein the first conductivity type is p-type.

17. The method of claim 15, further comprising forming a buffer layer on an upper surface of the substrate before performing the implantation process.

18. The method of claim 15, wherein performing the implantation comprises doping the substrate with dopants at a concentration equal to or greater than from about 10¹⁵ atoms/cm⁻³.

19. The method of claim 15, further comprising forming isolation structures in the epitaxial layer before forming the doped regions.

20. The method of claim 19, wherein at least one of the isolation structures has a bottom formed in an area of the barrier layer with the higher dopant concentration level.
